(19) United States
(12) Patent Application Publication
(10) Pub. No.: US 2022/0252982 A1
(43) Pub. Date: Aug. 11, 2022

(54) PHOTORESIST COMPOSITIONS AND METHODS OF MANUFACTURING INTEGRATED CIRCUIT DEVICE USING THE SAME

(71) Applicant: Samsung Electronics Co., Ltd., Suwon-si, (KR)

(72) Inventors: SUKKOO HONG, Suwon-si (KR); HYUNWOO KIM, Seongnam-si (KR); HYUNJI SONG, Anyang-si (KR)

(21) Appl. No.: 17/485,727

(22) Filed: Sep. 27, 2021

(30) Foreign Application Priority Data
Feb. 10, 2021 (KR) 10-2021-0019369

(51) Int. Cl. G03F 7/039; G03F 7/004; G03F 7/32

(52) U.S. Cl. CPC G03F 7/0392; G03F 7/327; G03F 7/0045

(57) ABSTRACT

Photoresist compositions may include a photosensitive polymer, a photoacid generator (PAG), and a solvent. The photosensitive polymer may include a first repeating unit having a structure of Formula:

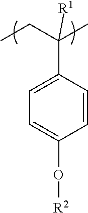

wherein R¹ is an oxygen atom or a methyl group, and R² is a nitrobenzyl-based photo-labile protecting group. In methods of manufacturing an integrated circuit (IC), a photoresist film is formed on a lower film by using the photoresist composition including the photosensitive polymer, the PAG, and the solvent. A hydroxystyrene repeating unit is deprotected in a first area of the photoresist film by exposing the first area of the photoresist film to light, and thus, the nitrobenzyl-based photo-labile protecting group is separated from the hydroxystyrene repeating unit and a sensitizer is generated from the hydroxystyrene repeating unit. The exposed first area is removed using a developer.

### CROSS-REFERENCE TO RELATED APPLICATION

This application is based on and claims priority under 35 U.S.C. § 119 to Korean Patent Application No. 10-2021-0019369, filed on Feb. 10, 2021, in the Korean Intellectual Property Office, the disclosure of which is incorporated by reference herein in its entirety.

### BACKGROUND

The inventive concept relates to a photoresist composition and a method of manufacturing an integrated circuit (IC) device using the same, and more particularly, to a photoresist composition including a photosensitive polymer including a photo-labile group and a method of manufacturing an IC device using the photoresist composition.

In recent years, the downscaling of semiconductor devices has rapidly progressed due to the development of electronic technology. Thus, a photolithography process, which is advantageous in forming fine patterns, may be required. In particular, there is a need for a technique that may increase light sensitivity in a photolithography process for manufacturing an IC device and improve a dissolution contrast for a developer between an exposed area and a non-exposed area of a photoresist film.

### SUMMARY

The inventive concept provides photoresist compositions, which may improve light sensitivity and contrast in a photolithography process for manufacturing an integrated circuit (IC) device.

The inventive concept also provides methods of manufacturing an IC device, which may increase light sensitivity in a photolithography process and may improve a dissolution contrast for a developer between an exposed area and a non-exposed area of a photoresist film to improve the dimensional precision of a pattern to be formed.

According to some embodiments of the inventive concept, there are provided photoresist compositions including a photosensitive polymer, a photoacid generator (PAG), and a solvent, and the photosensitive polymer includes a first repeating unit having a structure of Formula 1.

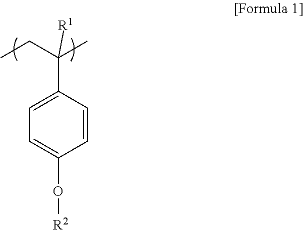

wherein R¹ is an oxygen atom or a methyl group, and R² is a nitrobenzyl-based photo-labile protecting group.

According to some embodiments of the inventive concept, there are provided photoresist compositions including a photosensitive polymer, a PAG, and a solvent. The photosensitive polymer has a structure of formula.

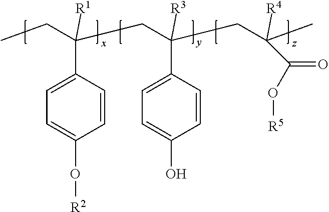

wherein R¹ is an oxygen atom or a methyl group, R² is a nitrobenzyl-based photo-labile protecting group, R³ and R⁴ are each independently a hydrogen atom or a methyl group, R⁵ is an acid-labile protecting group, and each of x/(x+y+z) and y/(x+y+z) is independently in a range of about 0.05 to about 0.4.

According to some embodiments of the inventive concept, there are provided methods of manufacturing an IC device. The method includes forming a photoresist film on a lower film using a photoresist composition including a photosensitive polymer including a hydrostyrene repeating unit comprising a nitrobenzyl-based photo-labile protecting group, a PAG, and a solvent. The hydroxystyrene repeating unit is deprotected in a first area of the photoresist film by exposing the first area of the photoresist film to light. Thus, the photo-labile protecting group is separated from the hydroxystyrene repeating unit and a sensitizer is generated from the hydroxystyrene repeating unit. The exposed first area is removed from the photoresist film using a developer to form a photoresist pattern including a non-exposed area of the photoresist film. The lower film is processed using the photoresist pattern.

### BRIEF DESCRIPTION OF THE DRAWINGS

Some embodiments of the inventive concept will be more clearly understood from the following detailed description taken in conjunction with the accompanying drawings in which:

FIG. 1 is a flowchart of a method of manufacturing an integrated circuit (IC) device, according to some embodiments of the inventive concept; and

FIGS. 2A to 2E are cross-sectional views illustrating a method of manufacturing an IC device, according to some embodiments of the inventive concept.

### DETAILED DESCRIPTION

Hereinafter, some embodiments of the inventive concept will be described in detail with reference to the accompanying drawings. The same reference numerals are used to denote the same elements in the drawings, and repeated descriptions thereof will be omitted.

A photoresist composition according to some embodiments of the inventive concept may include a photosensitive polymer including a hydroxystyrene repeating unit having a nitrobenzyl-based photo-labile protecting group, a photoacid generator (PAG), and a solvent.

The photosensitive polymer may include a first repeating unit represented by Formula 1.

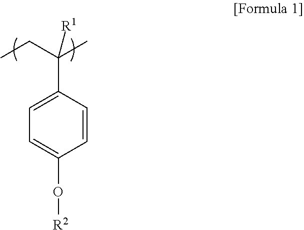

wherein R¹ denotes an oxygen atom or a methyl group, and R² denotes a nitrobenzyl-based photo-labile protecting group. In Formula 1, R² may include o-nitrobenzyl having a nitro group at an ortho position or derivatives thereof.

In example embodiments, the photosensitive polymer may further include at least one of a second repeating unit represented by Formula 2 and a third repeating unit represented by Formula 3.

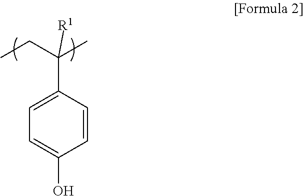

wherein R³ denotes a hydrogen atom or a methyl group.

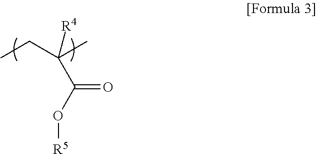

wherein R⁴ denotes a hydrogen atom or a methyl group, and R⁵ denotes an acid-labile protecting group.

For example, the photosensitive polymer may include a structure represented by Formula 4.

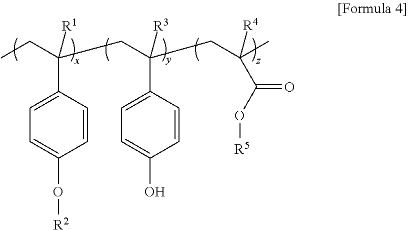

wherein R¹, R², R³, R⁴, and R⁵ are as defined above, and each of x/(x+y+z) and y/(x+y+z) is independently in a range of about 0.05 to about 0.4.

The photosensitive polymer represented by Formula 4 may have a weight-average molecular weight Mw of about 3,000 to about 50,000 Daltons, without being limited thereto.

In the first repeating unit represented by Formula 1, R² may have a structure represented by Formula 5.

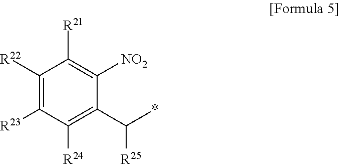

wherein each of R21, R²², R²³, and R²⁴ denotes independently a hydrogen atom, a C1 to C30 linear alkyl group, a C1 to C30 branched alkyl group, a C2 to C30 alkenyl group, a C2 to C30 alkynyl group, a C3 to C30 cycloalkyl group, a C6 to C30 aryl group, a C3 to C30 allyl group, a C1 to C30 alkoxy group, a C6 to C30 aryloxy group, a benzyl group, a halogen atom, a hydroxyl group, a thiol group, a thioether group, an amino group, a nitro group, a carboxyl group, a formate group, a formamido group, or a phosphide, or two adjacent groups (i.e., R²¹ and R²², R²² and R²³, or R²³ and R²⁴) selected from R²¹, R²², R²³, and R²⁴ may be linked to each other to form a cyclic acetal or a cyclic ketal. R²¹ and R²², R²² and R²³, or R²³ and R²⁴ may together form a cyclic acetal or a cyclic ketal. R²⁵ may be a hydrogen atom, a C1 to C30 linear alkyl group, a C1 to C30 branched alkyl group, a C2 to C30 alkenyl group, a C2 to C30 alkynyl group, a C3 to C30 cycloalkyl group, a C6 to C30 aryl group, a C3 to C30 allyl group, a C1 to C30 alkoxy group, a C6 to C30 aryloxy group, or a halogen atom, and “*” denotes a bonding site. Throughout the specification, a functional group (e.g., an alkyl group, an aryl group, and alkoxy group) includes both a substituted functional group and an unsubstituted functional group unless specified otherwise.

In example embodiments, in Formula 5, each of R²¹, R²², R²³, and R²⁴ may be a hydrogen atom, and R²⁵ may be any one selected from a hydrogen atom and a methyl group.

In other example embodiments, at least one of R²¹, R²², R²³, and R²⁴ may be a methoxy group, the remaining ones excluding the at least one of R²¹, R²², R²³, and R²⁴ may be hydrogen atoms, and R²⁵ may be any one selected from a hydrogen atom and a methyl group.

In yet other example embodiments, each of at least two of R²¹, R²², R²³, and R²⁴ may be a nitro group, the remaining ones excluding the at least two thereof may be hydrogen atoms, and R²⁵ may be any one selected from a hydrogen atom and a methyl group.

In an example, in Formula 5, each of R²¹, R²², R²³, R²⁴, and R²⁵ may be a hydrogen atom. In this case, in the first repeating unit represented by Formula 1, R² may be a 2-dinitrobenzyl group.

In another example, in Formula 5, each of R²¹, R²², R²³, and R²⁵ may be a hydrogen atom, and R²⁴ may be a nitro group. In this case, in the first repeating unit represented by Formula 1, R² may be a 2,6-dinitrobenzyl group.

In still another example, in Formula 5, each of R²² and R²³ may be a methoxy group, and each of R²¹, R²⁴, and R²⁵ may be a hydrogen atom. In this case, in the first repeating unit represented by Formula 1, R² may be a 6-nitroveratryloxycarbonyl group.

In yet another example, in Formula 5, R²² and R²³ may be linked to each other to form a methylene acetal, and each of R²¹, R²⁴, and R²⁵ may be a hydrogen atom. In this case, in the first repeating unit represented by Formula 1, R² may be a 6-nitropiperonyloxycarbonyl group.

In yet another example, in Formula 5, each of R²² and R²³ may be a methoxy group, each of R²¹ and R²⁴ may be a hydrogen atom, and R²⁵ may be a methyl group. In this case, in the first repeating unit represented by Formula 1, R² may be a methyl-6-nitroveratryloxycarbonyl group.

In yet another example, in Formula 5, R²² and R²³ may be linked to each other to form a methylene acetal, each of R²¹ and R²⁴ may be a hydrogen atom, and R²⁵ may be a methyl group. In this case, in the first repeating unit represented by Formula 1, R² may be a methyl-6-nitropiperonyl.

In Formulas 3 and 4, R⁵, which is the acid-labile protecting group, may be one selected from a substituted or unsubstituted t-butyl group and a C3 to C30 substituted or unsubstituted tertiary alicyclic group. As used herein, unless specified otherwise, the term “substituted” may refer to including at least one substituent, for example, a halogen atom (e.g., a fluorine (F) atom, a chlorine (Cl) atom, a bromine (Br) atom, or an iodine (I) atom), hydroxyl, amino, thiol, carboxyl, carboxylate, ester, amide, nitrile, sulfide, disulfide, nitro, C1 to C20 alkyl, C1 to C20 cycloalkyl, C2 to C20 alkenyl, C1 to C20 alkoxy, C2 to C20 alkenoxy, C6 to C30 aryl, C6 to C30 aryloxy, C7 to C30 alkylaryl, or a C7 to C30 alkylaryloxy group.

In example embodiments, in Formulas 3 and 4, R⁵ may have an unsubstituted structure. For example, in Formulas 3 and 4, R⁵ may include an unsubstituted t-butyl group or a C3 to C30 unsubstituted tertiary alicyclic group.

In other example embodiments, in Formulas 3 and 4, R⁵ may have a structure substituted with a first substituent. For example, in Formula 3, R⁵ may include a t-butyl group substituted with the first substituent or a C3 to C30 tertiary alicyclic group substituted with the first substituent. The first substituent may include a C1 to C10 alkyl group, a C1 to C10 alkoxy group, a halogen atom, a C1 to C10 halogenated alkyl group, a hydroxyl group, an unsubstituted C6 to C30 aryl group, or a C6 to C30 aryl group in which some of carbon atoms included in the first substituent are substituted with a halogen atom or a heteroatom-containing group. The halogen atom that may be included in the first substituent may be one selected from a F atom, a C1 atom, a Br atom, and an I atom. The halogenated alkyl group may include at least one halogen atom selected from a fluorine (F) atom, chlorine (Cl), bromine (Br), and iodine (I). The heteroatom may be an oxygen atom, a sulfur atom, or a nitrogen atom. For example, the heteroatom-containing group may be —O—, —C(═O)—O—, —O—C(═O)—, —C(═O)—, —O—C(═O)—O—, —C(═O)—NH—, —NH—, —S—, —S(═O)₂—, or —S(═O)₂—O—.

In example embodiments, in Formulas 3 and 4, R⁵ may include tert-butoxycarbonyl (t-BOC), isonorbornyl, 2-methyl-2-adamantyl, 2-ethyl-2-adamantyl, 3-tetrahydrofuranyl, 3-oxocyclohexyl, γ-butyllactone-3-yl, mavaloniclactone, γ-butyrolactone-2-yl, 3-methyl-γ-butyrolactone-3-yl, 2-tetrahydropyranyl, 2-tetrahydrofuranyl, 2,3-propylenecarbonate-1-yl, 1-methoxyethyl, 1-ethoxyethyl, 1-(2-methoxyethoxy)ethyl, 1-(2-acetoxyethoxy)ethyl, t-buthoxycarbonylmethyl, methoxymethyl, ethoxymethyl, trimethoxysilyl, or a triethoxysilyl group, without being limited thereto.

The PAG included in the photoresist composition according to some embodiments may generate an acid when exposed to light, for example, light selected from a krypton fluoride (KrF) excimer laser (248 nm), an argon fluoride (ArF) excimer laser (193 nm), a fluorine (F₂) excimer laser (157 nm), and/or an extreme ultraviolet (EUV) laser (13.5 nm). As used herein the term “and/or” includes any and all combinations of one or more of the associated listed items.

In example embodiments, the PAG may include triarylsulfonium salts, diaryliodonium salts, sulfonates, or a mixture thereof. For example, the PAG may include triphenylsulfonium triflate, triphenylsulfonium antimonate, diphenyliodonium triflate, diphenyliodonium antimonate, methoxydiphenyliodonium triflate, di-t-butyldiphenyliodonium triflate, 2,6-dinitrobenzyl sulfonates, pyrogallol tris(alkylsulfonates), N-hydroxysuccinimide triflate, norbornene-dicarboximide-triflate, triphenylsulfonium nonaflate, diphenyliodonium nonaflate, methoxydiphenyliodonium nonaflate, di-t-butyldiphenyliodonium nonaflate, N-hydroxysuccinimide nonaflate, norbornene-dicarboximide-nonaflate, triphenylsulfonium perfluorobutanesulfonate, triphenylsulfonium perfluorooctanesulfonate (PFOS), diphenyliodonium PFOS, methoxydiphenyliodonium PFOS, di-t-butyldiphenyliodonium triflate, N-hydroxysuccinimide PFOS, norbornene-dicarboximide PFOS, or a mixture thereof.

In the photoresist composition according to some embodiments, the PAG may be present in the photoresist composition in an amount of about 0.1% to about 5.0% by weight, based on the total weight of the photosensitive polymer, without being limited thereto.

In the photoresist composition according to some embodiments, the solvent may include an organic solvent. In example embodiments, the solvent may include at least one of ether, alcohol, glycol ether, an aromatic hydrocarbon compound, ketone, and ester. For example, the solvent may be selected from ethylene glycol monomethyl ether, ethylene glycol monoethyl ether, methyl cellosolve acetate, ethyl cellosolve acetate, diethylene glycol monomethyl ether, diethylene glycol monoethyl ether, propylene glycol, propylene glycol monomethyl ether, propylene glycol monomethyl ether acetate, propylene glycol monoethyl ether, propylene glycol monoethyl ether acetate, propylene glycol propyl ether acetate, propylene glycol monobutyl ether, propylene glycol monobutyl ether acetate, toluene, xylene, methyl ethyl ketone, cyclopentanone, cyclohexanone, ethyl 2-hydroxypropionate, ethyl 2-hydroxy-2-methylpropionate, ethyl ethoxyacetate, ethyl hydroxyacetate, methyl 2-hydroxy-3-methylbutanoate, methyl 3-methoxypropionate, ethyl 3-methoxypropionate, ethyl 3-ethoxypropionate, methyl 3-ethoxypropionate, methyl pyruvate, ethyl pyruvate, ethyl acetate, butyl acetate, ethyl lactate, and butyl lactate. The solvents described above may be used alone or in combination of at least two kinds thereof. In some embodiments, the amount of the solvent in the photoresist composition may be adjusted so that a solid content of the photoresist composition may range from about 3% to about 20% by weight.

The photoresist composition according to some embodiments may further include a basic quencher.

When an acid generated from the PAG included in the photoresist composition according to some embodiments diffuses into a non-exposed area of a photoresist film, the basic quencher may trap the acid in the non-exposed area of the photoresist film. Because the basic quencher is included in the photoresist composition according to some embodiments, after the photoresist film obtained from the photoresist composition is exposed, a problem caused by diffusion of an acid generated in an exposed area of the photoresist film into the non-exposed area thereof may be reduced or prevented.

In example embodiments, the basic quencher may include primary a aliphatic amine, a secondary aliphatic amine, a tertiary aliphatic amine, an aromatic amine, a heterocyclic ring-containing amine, a nitrogen-containing compound including a carboxyl group, a nitrogen-containing compound including a sulfonyl group, a nitrogen-containing compound including a hydroxyl group, a nitrogen-containing compound including a hydroxyphenyl group, an alcoholic nitrogen-containing compound, an amide, an imide, a carbamate, or an ammonium salt. For example, the basic quencher may include triethanolamine, triethyl amine, tributyl amine, tripropylamine, hexamethyl disilazan, aniline, N-methylaniline, N-ethylaniline, N-propylaniline, N,N-dimethylaniline, N,N-bis(hydroxyethyl)aniline, 2-methylaniline, 3-methylaniline, 4-methylaniline, ethylaniline, propylaniline, dimethylaniline, 2,6-diisopropylaniline, trimethylaniline, 2-nitroaniline, 3-nitroaniline, 4-nitroaniline, 2,4-dinitroaniline, 2,6-dinitroaniline, 3,5-dinitroaniline, N,N-dimethyltoluidine, or a combination thereof, but is not limited thereto.

In other example embodiments, the basic quencher may include a photo-labile base. The photo-labile base may include a compound, which generates acid due to exposure (e.g., exposure to light) and neutralizes the acid before exposure. The photo-labile base may lose the ability to trap the acid when decomposed due to exposure. Accordingly, when a partial region of a photoresist film formed using a chemically amplified photoresist composition including a basic quencher including the photo-labile base is exposed, the photo-labile base may lose alkalinity in an exposed area of the photoresist film, while the photo-labile base may trap acid in a non-exposed area of the photoresist film. Thus, a problem caused by diffusion of acid generated in the exposed area of the photoresist film into the non-exposed area of the photoresist film may be reduced or prevented.

The photo-labile base may include a carboxylate or sulfonate salt of a photo-labile cation. For example, the photo-labile cation may form a complex with an anion of C1 to C20 carboxylic acid. The carboxylic acid may be, for example, formic acid, acetic acid, propionic acid, tartaric acid, succinic acid, cyclohexylcarboxylic acid, benzoic acid, or salicylic acid, but is not limited thereto.

In the photoresist composition according to some embodiments, the basic quencher may be present in the photoresist composition in an amount of about 0.01% to about 5.0% by weight, based on a total weight of the photosensitive polymer, without being limited thereto.

In the photoresist composition according to some embodiments, the solvent may be contained at a content of the remaining percentage excluding the contents of main components including the photosensitive polymer and the PAG. In example embodiments, the solvent may be present in the photoresist composition in an amount of about 0.1% to about 99.7% by weight, based on the total weight of the photoresist composition.

In example embodiments, the photoresist composition according to some embodiments may further include at least one selected from a surfactant, a dispersant, a desiccant, and a coupling agent.

The surfactant may improve the coating uniformity and wettability of the photoresist composition. In example embodiments, the surfactant may include sulfuric acid ester salts, sulfonates, phosphate ester, soap, amine salts, quaternary ammonium salts, polyethylene glycol, alkylphenol ethylene oxide adducts, polyhydric alcohol, a nitrogen-containing vinyl polymer, or a combination thereof, without being limited thereto. For example, the surfactant may include alkylbenzene sulfonates, alkylpyridinium salts, polyethylene glycol, or quaternary ammonium salts. When the photoresist composition includes the surfactant, the surfactant may be present in the photoresist composition in an amount of about 0.001% to about 3% by weight, based on the total weight of the photoresist composition.

The dispersant may uniformly disperse respective components in the photoresist composition. In example embodiments, the dispersant may include an epoxy resin, polyvinyl alcohol, polyvinyl butyral, polyvinylpyrrolidone, glucose, sodium dodecyl sulfate, sodium citrate, oleic acid, linoleic acid, or a combination thereof, without being limited thereto. When the photoresist composition includes the dispersant, the dispersant may be present in the photoresist composition in an amount of about 0.001% to about 5% by weight, based on the total weight of the photoresist composition.

The desiccant may reduce or prevent adverse effects due to moisture in the photoresist composition. For example, the desiccant may prevent a metal included in the photoresist composition from being oxidized due to moisture. In example embodiments, the desiccant may include polyoxyethylene nonylphenolether, polyethylene glycol, polypropylene glycol, polyacrylamide, or a combination thereof, without being limited thereto. When the photoresist composition includes the desiccant, the desiccant may be present in the photoresist composition in an amount about 0.001% to about 10% by weight, based on the total weight of the photoresist composition.

The coupling agent may increase adhesion of the photoresist composition with a lower film when the lower film is coated with the photoresist composition. In example embodiments, the coupling agent may include a silane coupling agent. The silane coupling agent may include vinyl trimethoxysilane, vinyl triethoxysilane, vinyl trichlorosilane, vinyl tris(J3-methoxyethoxy)silane, 3-methacryl oxypropyl trimethoxysilane, 3-acryl oxypropyl trimethoxysilane, p-styryl trimethoxysilane, 3-methacryl oxypropyl methyldimethoxysilane, 3-methacryl oxypropyl methyldiethoxysilane, or trimethoxy[3-(phenylamino)propyl]silane, without being limited thereto. When the photoresist composition includes the coupling agent, the coupling agent may be present in the photoresist composition in an amount of about 0.001% to about 5% by weight, based on the total weight of the photoresist composition.

In the photoresist composition according to some embodiments, when the solvent includes only the organic solvent, the photoresist composition may further include water. In this case, water may be present in the photoresist composition in an amount of about 0.001% to about 0.1% by weight, based on the total weight of the photoresist composition.

The photoresist composition according to some embodiments may include the photosensitive polymer including the first repeating unit represented by Formula 1, that is, the hydroxystyrene repeating unit having the nitrobenzyl-based photo-labile protecting group. Accordingly, when the photoresist film obtained from the photoresist composition is exposed, the hydroxystyrene repeating unit, which is the first repeating unit, may be deprotected in the exposed area of the photoresist film, and thus, the nitrobenzyl-based photo-labile protecting group may be separated from the hydroxystyrene repeating unit and an acid (H⁺) may be generated.

Chemical equation 1 briefly shows a process in which, when exposed (e.g., exposed to light), the hydroxystyrene repeating unit having the nitrobenzyl-based photo-labile protecting group, which is the first repeating unit included in the photoresist composition according to some embodiments, is deprotected to separate a photo-labile protecting group and generate an acid (H⁺).

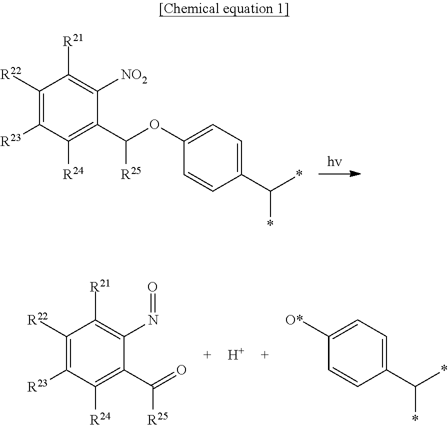

wherein “*” denotes a bonding site.

As shown in Chemical equation 1, the hydroxystyrene repeating unit may be deprotected in the exposed area of the photoresist film to separate the photo-labile protecting group from the hydroxystyrene repeating unit. As a result, a solubility of the photoresist film in a developer may be increased. In addition, the acid (H⁺) generated from the hydroxystyrene repeating unit may function as a sensitizer to improve sensitivity.

In the non-exposed area of the photoresist film, the hydroxystyrene repeating unit, which is the first repeating unit represented by Formula 1, may maintain a structure including a hydrophobic photo-labile protecting group as it is. Accordingly, a solubility of the non-exposed area of the photoresist film in the developer may be greatly reduced during the developing of the photoresist film.

Therefore, when a photolithography process for manufacturing an IC device is performed using the photoresist composition according to some embodiments, light sensitivity may be increased, and a sufficient dissolution contrast for a developer between the exposed area and the non-exposed area of the photoresist film may be ensured to improve resolution.

A vast amount of research has been conducted into an EUV lithography technique incorporating an exposure process using EUV light having a wavelength of about 13.5 nm as an advanced technique for superseding a lithography process using a KrF excimer laser (248 nm) and an ArF excimer laser (193 nm). An EUV lithography process may be based on a different action mechanism from the lithography process using the KrF excimer laser and the ArF excimer laser. The entire EUV lithography process may be performed in vacuum. Because an EUV lithography system lacks power required for a light source to irradiate laser light, there may be limit to sufficiently increasing a dose to generate a required amount of acid from a PAG, from among components of a photoresist composition, during an exposure process. Thus, when an EUV lithography process is performed using a typical photoresist composition, acid generation efficiency and an exposure speed may be low due to a relatively low dose provided by a light source of the EUV lithography system. Accordingly, it may be difficult to obtain a desired exposure sensitivity.

The photoresist composition according to some embodiments may include the photosensitive polymer including the hydroxystyrene repeating unit in which the o-nitrobenzyl-based photo-labile protecting group has the nitro group at the ortho position. Accordingly, as described above, light sensitivity may be increased during the photolithography process, and a sufficient dissolution contrast for a developer between the exposed area and the non-exposed area of the photoresist film may be ensured to improve resolution.

The photosensitive polymer included in the photoresist composition according to some embodiments may be easily synthesized using a known technique. An example process of synthesizing a photosensitive polymer is briefly described in Chemical equations 2 and 3.

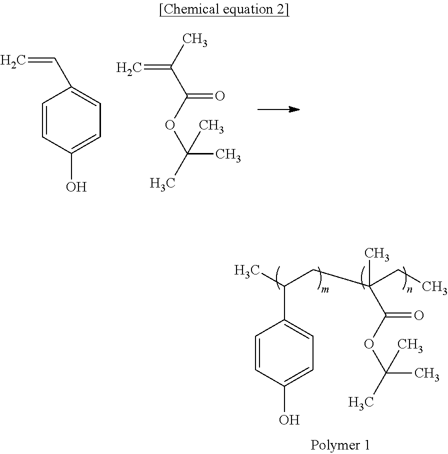

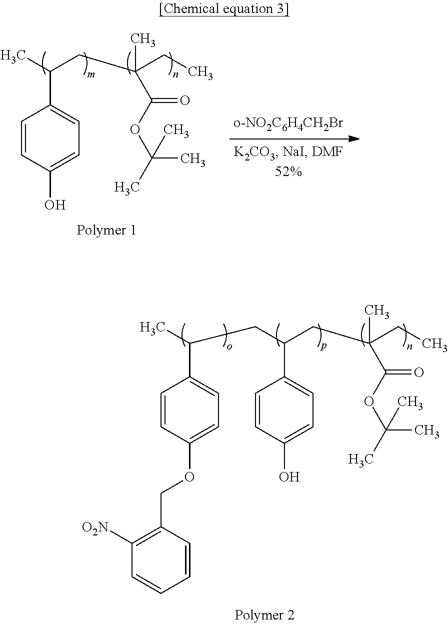

More specifically, as shown in Chemical equation 2, 50 mol % of acetyl hydroxystyrene, 50 mol % of t-butyl methacrylate, and 3 mol % of azobisisobutyronitril (AIBN) may be reacted with tetrahydrofuran (THF) for about 30 minutes, and the reacted product was treated with a NaOH solution to synthesize polymer 1. Thereafter, polymer 2 may be synthesized through a reaction shown in Chemical equation 3. In Chemical equations 2 and 3, m may be 5, n may be 5, o may be 2, and p may be 3. For example, the synthesis process according to Chemical equation 3 may be performed with reference to the disclosure of the paper (Harran et al., Angew. Chem. Int. Ed. 2001, 40, 4765-4769).

The photoresist composition according to some embodiments may be advantageously used to form a pattern having a relatively high aspect ratio. For example, the photoresist composition according to some embodiments may be advantageously used in a photolithography process for forming a pattern having a fine width, which is selected in the range of about 5 nm to about 100 nm.

Next, a method of manufacturing an IC device using the photoresist composition according to some embodiments will be described with reference to a specific example.

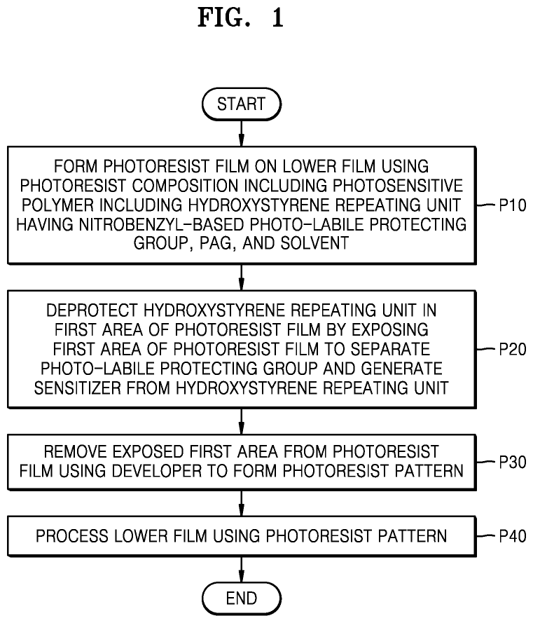

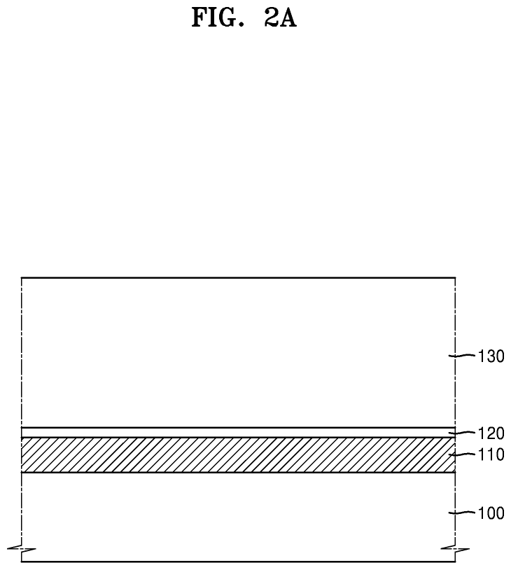

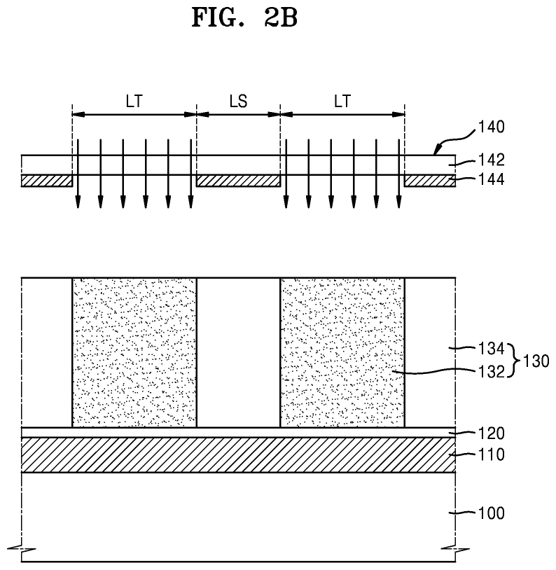

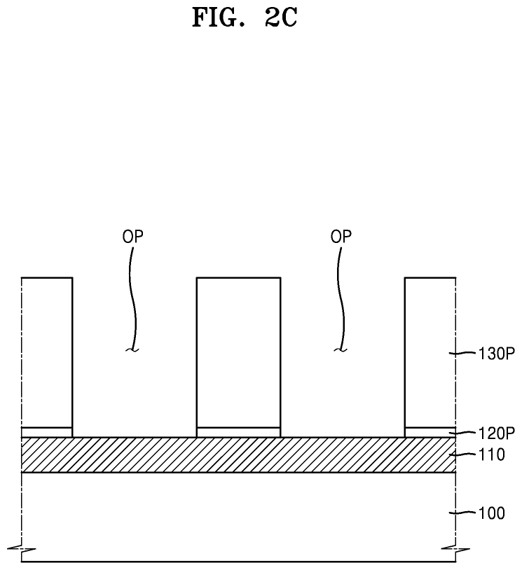

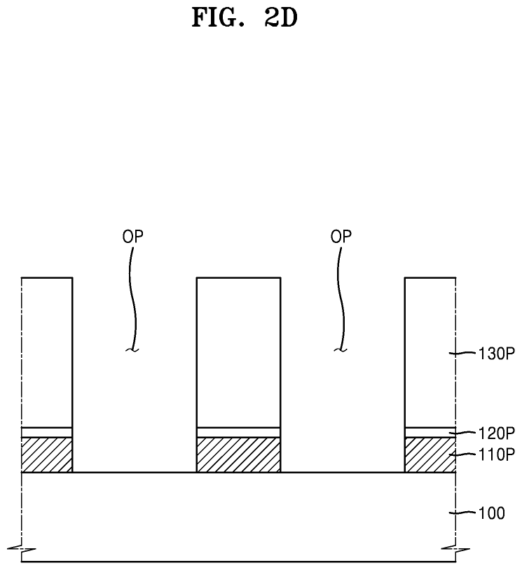

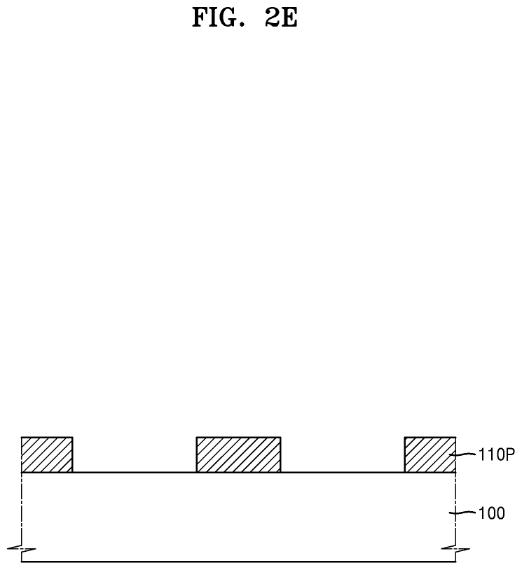

FIG. 1 is a flowchart of a method of manufacturing an IC device, according to some embodiments of the inventive concept. FIGS. 2A to 2E are cross-sectional views illustrating a method of manufacturing an IC device, according to some embodiments of the inventive concept.

Referring to FIGS. 1 and 2A, in process P10, a photoresist film 130 may be formed on a lower film using a photoresist composition according to some embodiments. The lower film may include a substrate 100 and a feature layer 110 formed on the substrate 100.

The photoresist film 130 may include a photosensitive polymer including a hydroxystyrene repeating unit having a nitrobenzyl-based photo-labile protecting group, a PAG, and a solvent, which are components of the photoresist composition according to some embodiments. A detailed configuration of the photoresist composition is as described above.

The substrate 100 may include a semiconductor substrate. The feature layer 110 may include an insulating film, a conductive film, or a semiconductor film. For example, the feature layer 110 may include a metal, an alloy, a metal carbide, a metal nitride, a metal oxynitride, a metal oxycarbide, a semiconductor, polysilicon, oxide, nitride, oxynitride, or a combination thereof, without being limited thereto.

In example embodiments, as shown in FIG. 2A, before the photoresist film 130 is formed on the feature layer 110, a developable bottom anti-reflective coating (DBARC) film 120 may be formed on the feature layer 110. In this case, the photoresist film 130 may be formed on the DBARC film 120. The DBARC film 120 may control reflection of light from a light source used during an exposure process for manufacturing an IC device or absorb reflected light from the feature layer 110 located thereunder. In example embodiments, the DBARC film 120 may include an organic anti-reflective coating (ARC) material for a KrF excimer laser, an ArF excimer laser, or any other light source. In example embodiments, the DBARC film 120 may include an organic component having a light-absorbing structure. The light-absorbing structure may include, for example, at least one benzene ring or a hydrocarbon compound in which benzene rings are fused. The DBARC film 120 may be formed to a thickness of about 20 nm to about 100 nm but is not limited thereto. In example embodiments, the DBARC film 120 may be omitted.

To form the photoresist film 130, a photoresist composition according to some embodiments of the inventive concept may be coated on the DBARC film 120 and annealed. The coating process may be performed using, for example, a spin coating process, a spray coating process, and a deep coating process. The process of annealing the photoresist composition may be performed at a temperature of about 80° C. to about 300° C. for about 10 seconds to about 100 seconds, without being limited thereto. A thickness of the photoresist film 130 may be several times to several hundred times a thickness of the DBARC film 120. The photoresist film 130 may be formed to a thickness of about 100 nm to about 6 μm but the inventive concept is not limited thereto.

Referring to FIGS. 1 and 2B, in process P20, a first area 132, which is a portion of the photoresist film 130, may be exposed.

The first area 132 of the photoresist film 130 may be exposed using a KrF excimer laser (248 nm), an ArF excimer laser (193 nm), an F₂ excimer laser (157 nm), or an EUV laser (13.5 nm).

In example embodiments, the photoresist film 130 may include the photosensitive polymer having the structure represented by Formula 4. In this case, when the first area 132 of the photoresist film 130 is exposed, an acid may be generated from the PAG in the first area 132, and the third repeating unit having the acid-labile protecting group denoted by R⁵ may be deprotected due to the acid generated from the PAG, and thus, the acid-labile protecting group may be separated from the third repeating unit.

In addition, when the first area 132 of the photoresist film 130 is exposed, in the first area 132 of the photoresist film 130, the reaction described above with reference to Chemical equation 1 may be caused in the first repeating unit having the nitrobenzyl-based photo-labile protecting group denoted by R² as represented by Formula 1, of the photosensitive polymer. That is, the first repeating unit having the nitrobenzyl-based photo-labile protecting group may be deprotected in the first area 132 of the photoresist film 130, and thus, the photo-labile protecting group may be separated from the first repeating unit, and an acid (H⁺) may be generated from the first repeating unit.

In addition, in the first area 132 of the photoresist film 130, the acid (H⁺) may be generated from the second repeating unit represented by Formula 2, of the photosensitive polymer. Accordingly, when the photoresist film 130 includes the photosensitive polymer having the structure represented by Formula 4, the acid (H⁺) generated from each of the first repeating unit and the second repeating unit may function as a sensitizer, thereby contributing to improving sensitivity.

While the photoresist film 130 is being exposed in process P20 of FIG. 1, as shown in Chemical equation 1, the first repeating unit represented by Formula 1 may be deprotected in the first area 132 of the photoresist film 130, which is exposed. Thus, the photo-labile protecting group may be separated from the first repeating unit. As a result, a solubility of the photoresist film 130 in a developer may be increased, and the acid (H⁺) generated from the first and second repeating units may function as a sensitizer to improve sensitivity.

In the second area 134, which is the non-exposed area of the photoresist film 130, the first repeating unit may maintain a structure including a hydrophobic photo-labile protecting group as it is. Accordingly, when the photoresist film 130 is developed in a subsequent process, a solubility of the second area 134 of the photoresist film 130 in the developer may be greatly lowered. Accordingly, a difference in solubility in a developer between the first area 132 of the photoresist film 130, which is exposed, and the second area 134 of the photoresist film 130, which is not exposed, may be increased. As a result, a pattern having a low line-edge roughness (LER) or a low line-width roughness (LWR) may be obtained in a final pattern, which is to be formed in the feature layer 110 in a subsequent process.

In example embodiments, to expose the first area 132 of the photoresist film 130, a photomask 140 having a plurality of light-shielding areas LS and a plurality of light-transmitting areas LT may be arranged at a predetermined position on the photoresist film 130, and the first area 132 of the photoresist film 130 may be exposed through the plurality of light-transmitting areas LT of the photomask 140. The first area 132 of the photoresist film 130 may be exposed using a KrF excimer laser (248 nm), an ArF excimer laser (193 nm), an F₂ excimer laser (157 nm), or an EUV laser (13.5 nm).

The photomask 140 may include a transparent substrate 142 and a plurality of light-shielding patterns 144 formed in the plurality of light-shielding areas LS on the transparent substrate 142. The transparent substrate 142 may include quartz. The plurality of light-shielding patterns 144 may include chromium (Cr). The plurality of light-transmitting areas LT may be defined by the plurality of light-shielding patterns 144. According to some embodiments, to expose the first area 132 of the photoresist film 130, a reflective photomask (not shown) for EUV exposure may be used instead of the photomask 140.

After the first area 132 of the photoresist film 130 is exposed in process P20 of FIG. 1, the photoresist film 130 may be annealed. The annealing of the photoresist film 130 may be performed at a temperature of about 50° C. to about 200° C. for about 10 seconds to about 100 seconds, without being limited thereto.

Referring to FIGS. 1 and 2C, in process P30, the photoresist film 130 may be developed using a developer to remove the first area 132 from the photoresist film 130. As a result, a photoresist pattern 130P including the second area 134 of the photoresist film 130, which is the non-exposed area, may be formed.

The photoresist pattern 130P may include a plurality of openings OP. After the photoresist pattern 130P is formed, a portion of the DBARC film 120, which is exposed through the plurality of openings OP, may be removed to form a DBARC pattern 120P.

In example embodiments, an alkali developer may be used to develop the photoresist film 130. The alkali developer may include, for example, 2.38% by weight of a tetramethylammonium hydroxide (TMAH) solution.

In the first area 132 of the photoresist film 130, the photo-labile protecting group may be separated from the first repeating unit by deprotecting the first repeating unit including the nitrobenzyl-based photo-labile protecting group in the photosensitive polymer. Thus, a solubility of the first area 132 of the photoresist film 130 in the developer may be increased. In contrast, in the second area 134 of the photoresist film 130, the first repeating unit including the nitrobenzyl-based photo-labile protecting group may not be deprotected but be maintained in a hydrophobic state. Thus, a solubility of the second area 134 of the photoresist film 130 in the developer may be low. Accordingly, the first area 132 may be cleanly removed during the developing of the photoresist film 130 by using the developer. After the photoresist film 130 is developed, residue defects, such as a footing phenomenon, may not occur, and the photoresist pattern 130P may obtain a vertical sidewall profile. As described above, by improving a profile of the photoresist pattern 130P, when the feature layer 110 is processed using the photoresist pattern 130P, a critical dimension (CD) of an intended processing region may be precisely controlled in the feature layer 110.

Referring to FIGS. 1 and 2D, in process P40, the feature layer 110 may be processed using the photoresist pattern 130P in the resultant structure of FIG. 2C.

To process the feature layer 110, various processes, such as a process of etching the feature layer 110 exposed by the openings OP of the photoresist pattern 130P, a process of implanting impurity ions into the feature layer 110, a process of forming an additional film on the feature layer 110 through the openings OP, and a process of modifying portions of the feature layer 110 through the openings OP, may be performed. FIG. 2D illustrates a process of forming a feature pattern 110P by etching the feature layer 110, which is exposed by the openings OP, as an example of processing the feature layer 110.

In other example embodiments, the process of forming the feature layer 110 may be omitted from the process described with reference to FIG. 2A. In this case, the substrate 100 may be processed using the photoresist pattern 130P instead of the process described with reference to the process P40 of FIG. 1 and FIG. 2D. For example, various processes, such as a process of etching a portion of the substrate 100 using the photoresist pattern 130P, a process of implanting impurity ions into a partial region of the substrate 100, a process of forming an additional film on the substrate 100 through the openings OP, and a process of modifying portions of the substrate 100 through the openings OP, may be performed.

Referring to FIG. 2E, the photoresist pattern 130P and the DBARC pattern 120P, which remain on the feature pattern 110P, may be removed from the resultant structure of FIG. 2D. The photoresist pattern 130P and the DBARC pattern 120P may be removed using an ashing process and a strip process.

In the method of manufacturing an IC device according to some embodiments described with reference to FIGS. 1 and 2A to 2E, a difference in acidity between the exposed area and the non-exposed area may be increased to increase solubility in the developer between the exposed area and the non-exposed area of the photoresist film 130 obtained using the photoresist composition according to some embodiments. Thus, an LER and an LWR may be reduced in the photoresist pattern 130P obtained from the photoresist film 130 to provide a high pattern fidelity. Accordingly, when a subsequent process is performed on the feature layer 110 and/or the substrate 100 using the photoresist pattern 130P, a dimensional precision may be improved by precisely controlling critical dimensions of processing regions or patterns to be formed on the feature layer 110 and/or the substrate 100. In addition, a CD distribution of patterns to be formed on the substrate 100 may be uniformly controlled, and the productivity of a process of manufacturing an IC device may be increased.

While the inventive concept has been particularly shown and described with reference to some example embodiments thereof, it will be understood that various changes in form and details may be made therein without departing from the scope of the following claims.

What is claimed is:

1. A photoresist composition comprising:
a photosensitive polymer;
a photoacid generator (PAG); and
a solvent,
wherein the photosensitive polymer comprises a first repeating unit having a structure of Formula 1: 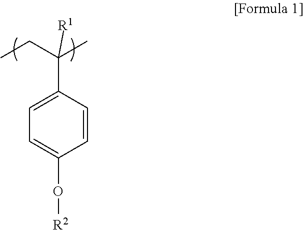
wherein R¹ is an oxygen atom or a methyl group, and R² is a nitrobenzyl-based photo-labile protecting group.

2. The photoresist composition of claim 1, wherein the photosensitive polymer further comprises a second repeating unit having a structure of Formula 2 and/or a third repeating unit having a structure of Formula 3: 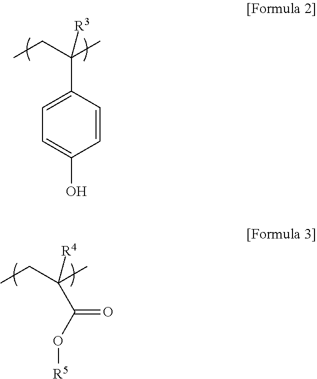
wherein R³ is a hydrogen atom or a methyl group,
R⁴ is a hydrogen atom or a methyl group, and
R⁵ is an acid-labile protecting group.

3. The photoresist composition of claim 1, wherein the photosensitive polymer comprises a structure of Formula 4: 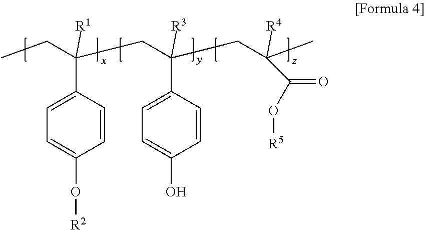
wherein R¹ and R² are each as defined in claim 1,
R³ and R⁴ are each independently a hydrogen atom or a methyl group,
R⁵ is an acid-labile protecting group, and
each of x/(x+y+z) and y/(x+y+z) is independently in a range of about 0.05 to about 0.4.

4. The photoresist composition of claim 1, wherein R² has a structure of Formula 5: 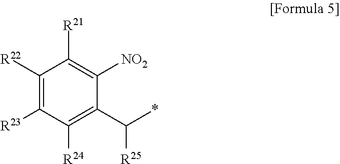
wherein R²¹, R²², R²³, and R²⁴ are each independently a hydrogen atom, a C1 to C30 linear alkyl group, a C1 to C30 branched alkyl group, a C2 to C30 alkenyl group, a C2 to C30 alkynyl group, a C3 to C30 cycloalkyl group, a C6 to C30 aryl group, a C3 to C30 allyl group, a C1 to C30 alkoxy group, a C6 to C30 aryloxy group, a benzyl group, a halogen atom, a hydroxyl group, a thiol group, a thioether group, an amino group, a nitro group, a carboxyl group, a formate group, a formamido group, or a phosphide group, or R²¹ and R¹¹, R²² and R²³, or R²³ and R²⁴ together form a cyclic acetal or a cyclic ketal,
R²⁵ is a hydrogen atom, a C1 to C30 linear alkyl group, a C1 to C30 branched alkyl group, a C2 to C30 alkenyl group, a C2 to C30 alkynyl group, a C3 to C30 cycloalkyl group, a C6 to C30 aryl group, a C3 to C30 allyl group, a C1 to C30 alkoxy group, a C6 to C30 aryloxy group, or a halogen atom, and
* is a bonding site.

5. The photoresist composition of claim 4, wherein each of R²¹, R²², R²³, and R²⁴ is a hydrogen atom, and R²⁵ is a hydrogen atom or a methyl group.

6. The photoresist composition of claim 4, wherein at least one of R²¹, R²², R²³, and R²⁴ is a methoxy group, and each of the remaining ones of R²¹, R²², R²³, and R²⁴ is a hydrogen atom, and wherein R²⁵ is a hydrogen atom or a methyl group.

7. The photoresist composition of claim 4, wherein each of at least two of R²¹, R²², R²³, and R²⁴ is a nitro group, and each of the remaining ones of R²¹, R²², R², and R²⁴ is a hydrogen atom, and wherein R²⁵ is a hydrogen atom or a methyl group.

8. The photoresist composition of claim 1, further comprising a basic quencher.

9. The photoresist composition of claim 8, wherein the basic quencher includes a primary aliphatic amine, a secondary aliphatic amine, a tertiary aliphatic amine, an aromatic amine, a heterocyclic ring-containing amine, a nitrogen-containing compound including a carboxyl group, a nitrogen-containing compound including a sulfonyl group, a nitrogen-containing compound including a hydroxyl group, a nitrogen-containing compound including a hydroxyphenyl group, an alcoholic nitrogen-containing compound, an amide, an imide, a carbamate, or an ammonium salt.

10. The photoresist composition of claim 8, wherein the basic quencher comprises a photo-labile base.

11. A photoresist composition comprising:
a photosensitive polymer;
a photoacid generator (PAG); and
a solvent,
wherein the photosensitive polymer has a structure of Formula: 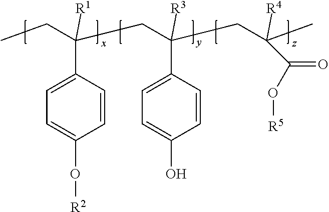
wherein R¹ is an oxygen atom or a methyl group,
R² is a nitrobenzyl-based photo-labile protecting group,
R³ and R⁴ are each independently a hydrogen atom or a methyl group,
R⁵ is an acid-labile protecting group, and
each of x/(x+y+z) and y/(x+y+z) is independently in a range of about 0.05 to about 0.4.

12. The photoresist composition of claim 11, wherein R² is a protecting group comprising o-nitrobenzyl or a derivative thereof.

13. The photoresist composition of claim 11, wherein R² has a structure of Formula: 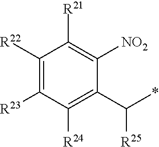
wherein R²¹, R²², R²³, and R²⁴ are each independently a hydrogen atom, a C1 to C30 linear alkyl group, a C1 to C30 branched alkyl group, a C2 to C30 alkenyl group, a C2 to C30 alkynyl group, a C3 to C30 cycloalkyl group, a C6 to C30 aryl group, a C3 to C30 allyl group, a C1 to C30 alkoxy group, a C6 to C30 aryloxy group, a benzyl group, a halogen atom, a hydroxyl group, a thiol group, a thioether group, an amino group, a nitro group, a carboxyl group, a formate group, a formamido group, or a phosphide group, or R²¹ and R²², R²² and R²³, or R²³ and R²⁴ together form a cyclic acetal or a cyclic ketal,
R²⁵ is a hydrogen atom, a C1 to C30 linear alkyl group, a C1 to C30 branched alkyl group, a C2 to C30 alkenyl group, a C2 to C30 alkynyl group, a C3 to C30 cycloalkyl group, a C6 to C30 aryl group, a C3 to C30 allyl group, a C1 to C30 alkoxy group, a C6 to C30 aryloxy group, or a halogen atom, and
is a bonding site.

14. The photoresist composition of claim 13, wherein each of R²¹, R²², R²³, and R²⁴ is a hydrogen atom, and R²⁵ is a hydrogen atom or a methyl group.

15. The photoresist composition of claim 13, wherein at least one of R²¹, R²², R²³, and R²⁴ is a methoxy group, and each of the remaining ones of R²¹, R²², R²³, and R²⁴ is a hydrogen atom, and wherein R²⁵ is a hydrogen atom or a methyl group.

16. The photoresist composition of claim 13, wherein each of at least two of R²¹, R²², R²³, and R²⁴ is a nitro group, and each of the remaining ones of R²¹, R²², R²³, and R²⁴ is a hydrogen atom, and wherein R²⁵ is a hydrogen atom or a methyl group.

17. The photoresist composition of claim 11, wherein R² is a 2-nitrobenzyl group, a 2, 6-nitrobenzyl group, a 6-nitroveratryloxycarbonyl group, a 6-nitropiperonyloxycarbonyl group, a methyl-6-nitroveratryloxycarbonyl group, or a methyl-6-nitropiperonyl group.

18. The photoresist composition of claim 11, further comprising a basic quencher.

19. A method of manufacturing an integrated circuit (IC), the method comprising:
forming a photoresist film on a lower film using a photoresist composition, the photoresist composition comprising a photosensitive polymer that comprises a hydroxystyrene repeating unit comprising a nitrobenzyl-based photo-labile protecting group, a photoacid generator (PAG), and a solvent;
deprotecting the hydroxystyrene repeating unit in a first area of the photoresist film by exposing the first area of the photoresist film to light to separate the nitrobenzyl-based photo-labile protecting group from the hydroxystyrene repeating unit and to generate a sensitizer from the hydroxystyrene repeating unit, thereby providing an exposed first area;
removing the exposed first area from the photoresist film using a developer to form a photoresist pattern comprising a non-exposed area of the photoresist film; and
processing the lower film using the photoresist pattern.

20. The method of claim 19, wherein the photosensitive polymer has a structure of Formula: 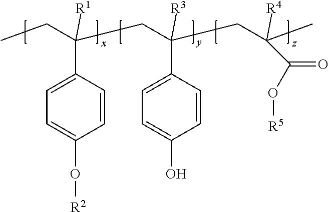
wherein R¹ is an oxygen atom or a methyl group,
R² is a nitrobenzyl-based photo-labile protecting group,
R³ and R⁴ are each independently a hydrogen atom or a methyl group,
R⁵ is an acid-labile protecting group, and
each of x/(x+y+z) and y/(x+y+z) is independently in a range of about 0.05 to about 0.4.
